(19) United States
(12) Patent Application Publication
(10) Pub. No.: US 2025/0248222 A1
(43) Pub. Date: Jul. 31, 2025

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Wang Woo LEE, Yongin-si (KR)

(21) Appl. No.: 18/795,008

(22) Filed: Aug. 5, 2024

(30) Foreign Application Priority Data
Jan. 26, 2024 (KR) 10-2024-0012647

(51) Int. Cl. H10K 59/122; H10K 59/80; H10K 102/00

(52) U.S. Cl. CPC H10K 59/122; H10K 59/873; H10K 2102/351

(57) ABSTRACT

A display device includes a substrate including first and second emission areas, a pixel-defining layer defining the first and second emission areas, a first light-emitting element above the substrate in the first emission area, a second light-emitting element above the substrate in the second emission area, a first bank above the pixel-defining layer, and a second bank above the first bank, and including a side surface that protrudes more than a side surface of the first bank and that is depressed more than a side surface of the pixel-defining layer, wherein a distance between the side surface of the pixel-defining layer and the side surface of the second bank adjacent to the first emission area is greater than a distance between the side surface of the pixel-defining layer and the side surface of the second bank adjacent to the second emission area.

### CROSS-REFERENCE TO RELATED APPLICATION

The present application claims priority to, and the benefit of, Korean Patent Application No. 10-2024-0012647, filed on Jan. 26, 2024, in the Korean Intellectual Property Office, the disclosure of which in its entirety is herein incorporated by reference.

### BACKGROUND

### 1. Field

The present disclosure relates to a display device.

### 2. Description of the Related Art

As the information society develops, the demand for display devices for displaying images has increased and diversified. For example, display devices have been applied to various electronic devices, such as smartphones, digital cameras, laptop computers, navigation devices, and smart televisions. The display devices may be flat panel display devices, such as liquid crystal display devices, field emission display devices, or organic light-emitting display devices. Among such flat panel display devices, a light-emitting display device may display an image without a backlight unit for providing light to a display panel because each of pixels of the display panel includes light-emitting elements that may emit light by themselves.

Recently, the display devices have been applied to glasses-type devices for providing virtual reality and augmented reality. The display device is implemented in a very small size of about 2 inches or less to be applied to the glasses-type device, but should have a high pixel integration degree to be implemented with high resolution. For example, the display device may have a high pixel integration degree of about 400 pixels per inch (PPI) or more.

When the display device is implemented in the very small size, but has the high pixel integration degree as described above, areas of emission areas where light-emitting elements are located may be reduced, and thus it may be difficult to implement light-emitting elements separated from each other for each emission area through a mask process.

### SUMMARY

Aspects of the present disclosure provide a display device capable of forming light-emitting layers or common electrodes separated from each other for each emission area without a mask process.

Aspects of the present disclosure also provide a high-resolution display device having wide substantially uniform emission areas.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate including a first emission area and a second emission area spaced apart, a pixel-defining layer including side surfaces defining the first emission area and the second emission area, a first light-emitting element above the substrate in the first emission area, and including a first pixel electrode, a first light-emitting layer, and a first common electrode, a second light-emitting element above the substrate in the second emission area, and including a second pixel electrode, a second light-emitting layer, and a second common electrode, a first bank above the pixel-defining layer, and a second bank above the first bank, and including a side surface that protrudes more than a side surface of the first bank and that is depressed more than the side surface of the pixel-defining layer, wherein a distance between the side surface of the pixel-defining layer and the side surface of the second bank adjacent to the first emission area is greater than a distance between the side surface of the pixel-defining layer and the side surface of the second bank adjacent to the second emission area.

An area of the second emission area may be greater than an area of the first emission area.

A distance between the side surface of the second bank and the side surface of the first bank adjacent to the first emission area may be greater than a distance between the side surface of the second bank and the side surface of the first bank adjacent to the second emission area.

In plan view, the pixel-defining layer may include exposed areas that are not covered with the second bank, wherein a width of one of the exposed areas of the pixel-defining layer surrounding the first emission area is greater than a width of another of the exposed areas of the pixel-defining layer surrounding the second emission area.

The substrate may further include a third emission area having an area that is greater than the area of the first emission area and greater than the area of the second emission area.

A distance between the side surface of the pixel-defining layer and the side surface of the second bank adjacent to the third emission area may be less than the distance between the side surface of the pixel-defining layer and the side surface of the second bank adjacent to the first emission area.

The distance between the side surface of the pixel-defining layer and the side surface of the second bank adjacent to the third emission area may be less than a distance between the side surface of the pixel-defining layer and the side surface of the second bank adjacent to the second emission area.

The distance between the side surface of the pixel-defining layer and the side surface of the second bank adjacent to the third emission area may be substantially equal to a distance between the side surface of the pixel-defining layer and the side surface of the second bank adjacent to the second emission area.

The first light-emitting layer may include a first area including a thickness of about 95% or more of a thickness of the first light-emitting layer at a point where the thickness of the first light-emitting layer is greatest, wherein an area of the first area of the first light-emitting layer is about 70% or more of an area of the first emission area.

A resolution of the display device may be about 1500 pixels per inch (ppi) or more.

The first common electrode and the second common electrode may be spaced apart.

The pixel-defining layer may be spaced apart from an upper surface of the first pixel electrode and an upper surface of the second pixel electrode.

The display device may further include a residual pattern between the first pixel electrode and the pixel-defining layer, and between the second pixel electrode and the pixel-defining layer.

The display device may further include a first inorganic layer above the first common electrode and the second bank, and a second inorganic layer above the second common electrode and the second bank, and spaced apart from the first inorganic layer.

The first inorganic layer may be spaced apart from an upper surface of the second bank, wherein the second inorganic layer is spaced apart from the upper surface of the second bank.

The display device may further include an organic encapsulation layer in a space between the first inorganic layer and the second bank, and in a space between the second inorganic layer and the second bank.

According to one or more embodiments of the present disclosure, a display device includes a substrate including a first emission area, and a second emission area spaced apart from the first emission area and including a greater area than the first emission area, a pixel-defining layer including side surfaces defining the first emission area and the second emission area, a first light-emitting element above the substrate in the first emission area, and including a first pixel electrode, a first light-emitting layer, and a first common electrode, a second light-emitting element above the substrate in the second emission area, and including a second pixel electrode, a second light-emitting layer, and a second common electrode, a first bank above the pixel-defining layer, and a second bank above the first bank, and including a side surface that protrudes more than a side surface of the first bank and that is depressed more than the side surface of the pixel-defining layer, wherein a width of an area where the pixel-defining layer and the first light-emitting layer overlap in a thickness direction of the substrate is greater than a width of an area where the pixel-defining layer and the second light-emitting layer overlap each other in the thickness direction.

The first light-emitting layer may include a first area including a thickness of about 95% or more of a thickness of the first light-emitting layer at a point where the thickness of the first light-emitting layer is greatest, wherein an area of the first area of the first light-emitting layer is about 70% or more of an area of the first emission area.

According to one or more embodiments of the present disclosure, a display device includes a substrate including a first emission area, a second emission area, and a third emission area spaced apart from each other, a pixel-defining layer including side surfaces defining the first emission area, the second emission area, and the third emission area, a first light-emitting element above the substrate in the first emission area, and including a first pixel electrode, a first light-emitting layer, and a first common electrode, a second light-emitting element above the substrate in the second emission area, and including a second pixel electrode, a second light-emitting layer, and a second common electrode, a first bank above the pixel-defining layer, and a second bank above the first bank, and including a side surface that protrudes more than a side surface of the first bank and that is depressed more than the side surface of the pixel-defining layer, wherein the first emission area, the second emission area, and the third emission area include different respective areas, and wherein a distance between the side surface of the pixel-defining layer and the side surface of the second bank adjacent to the first emission area, a distance between the side surface of the pixel-defining layer and the side surface of the second bank adjacent to the second emission area, and a distance between the side surface of the pixel-defining layer and the side surface of the second bank adjacent to the third emission area are different from each other.

A distance between the side surface of the second bank and the side surface of the first bank adjacent to the first emission area, a distance between the side surface of the second bank and the side surface of the first bank adjacent to the second emission area, and a distance between the side surface of the second bank and the side surface of the first bank adjacent to the third emission area may be substantially equal.

Detailed contents of other embodiments are described in a detailed description and are illustrated in the drawings.

With a display device according to one or more embodiments, by making areas where a pixel-defining layer is exposed different from each other depending on emission areas, it is possible to decrease a ratio of a non-uniform emission area in a narrow emission area, and to increase emission efficiency.

The aspects of the present disclosure are not limited to the aforementioned aspects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a cross-sectional view of the display device of FIG. 1 viewed from the side;

FIG. 3 is a top view of a light-emitting element layer of the display device according to one or more embodiments;

FIG. 4 is a cross-sectional view illustrating a portion of the display device according to one or more embodiments;

FIG. 5 is a cross-sectional view illustrating a light-emitting element layer and a thin film encapsulation layer of the display device according to one or more embodiments;

FIGS. 6A and 7A, and FIGS. 6B and 7B are, respectively, cross-sectional views illustrating substantially uniform deposition and non-uniform deposition of light-emitting layers when widths of exposed portions of a pixel-defining layer are the same as each other, and top views of emission areas;

FIGS. 8A and 8B are, respectively, a cross-sectional view illustrating substantially uniform deposition and non-uniform deposition of a light-emitting layer of the display device according to one or more embodiments, and a top view of an emission area;

FIG. 9 is a top view of a light-emitting element layer of a display device according to one or more other embodiments; and

FIG. 10 is a cross-sectional view illustrating a light-emitting element layer and a thin film encapsulation layer of the display device according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrases “in plan view” or “top view” mean when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present.

The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

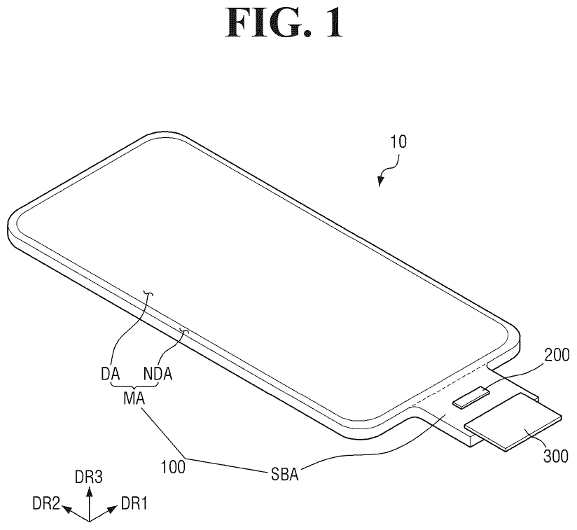

FIG. 1 is a perspective view illustrating a display device according to one or more embodiments.

Referring to FIG. 1, a display device 10 according to one or more embodiments may be included in an electronic device to provide a screen displayed on the electronic device. The electronic device may refer to all electronic devices that provide display screens. For example, televisions, laptop computers, monitors, billboards, the Internet of Things (IoT), mobile phones, smartphones, tablet personal computers (PCs), electronic watches, smart glasses, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the electronic device.

A shape of the display device 10 may be variously changed. For example, the display device 10 may have a shape that is similar to a rectangular shape having short sides in a first direction DR1, and long sides in a second direction DR2. A corner where the short side in the first direction DR1 and the long side in the second direction DR2 meet may be rounded with a curvature, but is not limited thereto, and may also be right-angled. The shape of the display device 10 in plan view is not limited to the rectangular shape, and may be a shape similar to other polygonal shapes, a circular shape, or an elliptical shape.

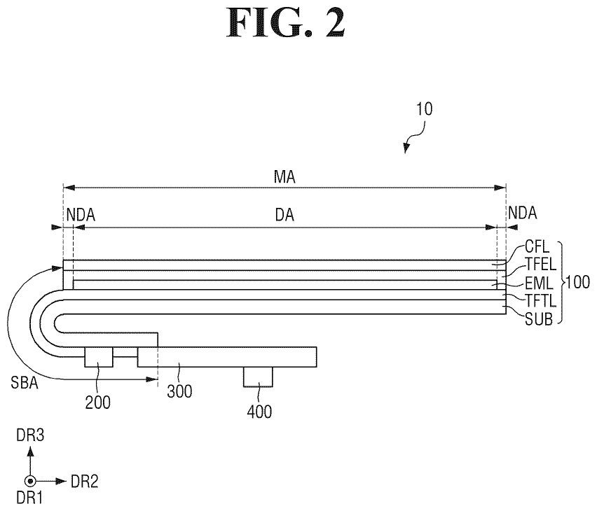

The display device 10 may include a display panel 100, a display driver 200, a circuit board 300, and a touch driver 400 (e.g., see FIG. 2).

The display panel 100 may include a main area MA and a sub-area SBA. The main area MA may include a display area DA including pixels for displaying an image, and a non-display area NDA located around the display area DA (e.g., in plan view). The display area DA may emit light from a plurality of emission areas or a plurality of opening areas. For example, the display panel 100 may include pixel circuits including switching elements, a pixel-defining layer defining the emission areas or the opening areas, and self-light-emitting elements.

For example, the self-light-emitting element may include at least one of an organic light-emitting diode (LED) including an organic light-emitting layer, a quantum dot LED including a quantum dot light-emitting layer, an inorganic LED including an inorganic semiconductor, or a micro LED, but is not limited thereto.

A plurality of pixels, a plurality of scan lines, a plurality of data lines, and a plurality of power lines may be located in the display area DA. Each of the plurality of pixels may be defined as a minimum unit for emitting light, and each of the self-light-emitting elements described above may be each of the pixels. The plurality of scan lines may supply scan signals received from a scan driver to the plurality of pixels. The plurality of data lines may supply data voltages received from the display driver 200 to the plurality of pixels. The plurality of power lines may supply source voltages received from the display driver 200 to the plurality of pixels.

The non-display area NDA may be an area outside the display area DA. The non-display area NDA may be defined as an edge area of the main area MA of the display panel 100. The non-display area NDA may include the scan driver for supplying the scan signals to the scan lines, and fan-out lines connecting the display driver 200 and the display area DA to each other.

The sub-area SBA may be an area extending from one side of the main area MA. The sub-area SBA may include a flexible material that may be bent, folded, and/or rolled. For example, when the sub-area SBA is bent, the sub-area SBA may overlap the main area MA in a thickness direction (third direction DR3). The sub-area SBA may include the display driver 200 and pad parts connected to the circuit board 300. In one or more other embodiments, the sub-area SBA may be omitted, and the display driver 200 and the pad parts may be located in the non-display area NDA.

The display driver 200 may output signals and voltages for driving the display panel 100. The display driver 200 may supply the data voltages to the data lines. The display driver 200 may supply the source voltages to the power lines, and may supply scan control signals to the scan driver. The display driver 200 may be formed as an integrated circuit (IC), and may be mounted on the display panel 100 in a chip-on-glass (COG) manner, a chip-on-plastic (COP) manner, or an ultrasonic bonding manner. As an example, the display driver 200 may be located in the sub-area SBA, and may overlap the main area MA in the thickness direction (third direction DR3) by bending of the sub-area SBA. As another example, the display driver 200 may be mounted on the circuit board 300.

The circuit board 300 may be attached onto the pad parts of the display panel 100 using an anisotropic conductive film (ACF). Lead lines of the circuit board 300 may be electrically connected to the pad parts of the display panel 100. The circuit board 300 may be a flexible printed circuit board, a printed circuit board, or a flexible film, such as a chip on film.

FIG. 2 is a cross-sectional view of the display device of FIG. 1 viewed from the side. For example, FIG. 2 illustrates a side surface of the display device of FIG. 1 in a state in which the display device is folded.

Referring to FIG. 2, the display panel 100 may include a substrate SUB, a thin film transistor layer TFTL, a light-emitting element layer EML, a thin film encapsulation layer TFEL, and a color filter layer CFL.

The substrate SUB may be a base substrate or a base member. The substrate SUB may be a flexible substrate that may be bent, folded, and rolled. For example, the substrate SUB may include a polymer resin, such as polyimide (PI), but is not limited thereto. In one or more other embodiments, the substrate SUB may include a glass material or a metal material.

The thin film transistor layer TFTL may be located on the substrate SUB. The thin film transistor layer TFTL may include a plurality of thin film transistors constituting pixel circuits of pixels. The thin film transistor layer TFTL may further include scan lines, data lines, power lines, scan control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. For example, when the scan driver is formed on one side of the non-display area NDA of the display panel 100, the scan driver may include thin film transistors.

The thin film transistor layer TFTL may be located in the display area DA, the non-display area NDA, and the sub-area SBA. The thin film transistors of each of the pixels, the scan lines, the data lines, and the power lines of the thin film transistor layer TFTL may be located in the display area DA. The scan control lines and the fan-out lines of the thin film transistor layer TFTL may be located in the non-display area NDA. The lead lines of the thin film transistor layer TFTL may be located in the sub-area SBA.

The light-emitting element layer EML may be located on the thin film transistor layer TFTL. The light-emitting element layer EML may include a plurality of light-emitting elements each including a first electrode, a second electrode, and a light-emitting layer to emit light, and may include a pixel-defining layer defining the pixels. The plurality of light-emitting elements of the light-emitting element layer EML may be located in the display area DA.

In one or more embodiments, the light-emitting layer may be an organic light-emitting layer including an organic material. The light-emitting layer may include a hole-transporting layer, an organic light-emitting layer, and an electron-transporting layer. When the first electrode receives a voltage through the thin film transistor of the thin film transistor layer TFTL and the second electrode receives a cathode voltage, holes and electrons may move to the organic light-emitting layer through the hole-transporting layer and the electron-transporting layer, respectively, and may be combined with each other in the organic light-emitting layer to emit light.

In one or more other embodiments, the light-emitting element may include a quantum dot light-emitting diode including a quantum dot light-emitting layer, an inorganic light-emitting diode including an inorganic semiconductor, or a micro light-emitting diode.

The thin film encapsulation layer TFEL may cover an upper surface and side surfaces of the light-emitting element layer EML, and may protect the light-emitting element layer EML. The thin film encapsulation layer TFEL may include at least one inorganic film and at least one organic film for encapsulating the light-emitting element layer EML.

The color filter layer CFL may be located on the thin film encapsulation layer TFEL. The color filter layer CFL may include a plurality of color filters respectively corresponding to the plurality of emission areas. Each of the color filters may selectively transmit light of a corresponding wavelength therethrough, and may block or absorb light of other wavelengths. The color filter layer CFL may absorb some of light introduced from the outside of the display device 10 to reduce reflected light by external light. Accordingly, the color filter layer CFL may reduce or prevent distortion of colors due to external light reflection.

Because the color filter layer CFL is directly located on the thin film encapsulation layer TFEL, the display device 10 may not require a separate substrate for the color filter layer CFL. Accordingly, a thickness of the display device 10 may be relatively small.

In some embodiments, the display device 10 may further include an optical device. The optical device may emit or receive light of infrared, ultraviolet, and visible light bands. For example, the optical device may be an optical sensor sensing light incident on the display device 10, such as a proximity sensor, an illuminance sensor, a camera sensor, a fingerprint sensor, or an image sensor.

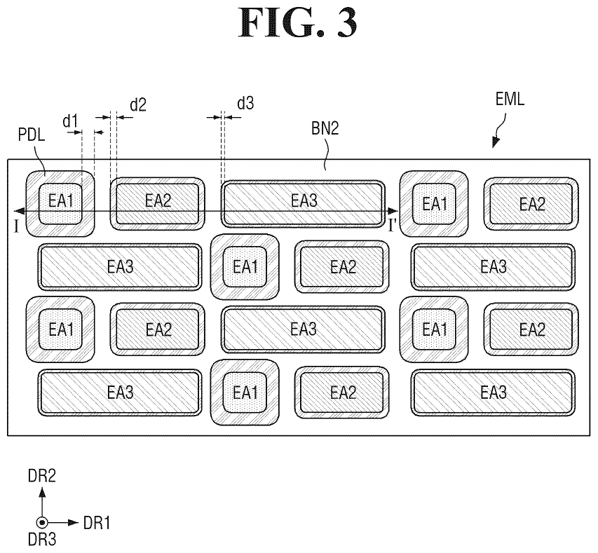

FIG. 3 is a top view illustrating a light-emitting element layer EML of the display device 10 according to one or more embodiments. FIG. 3 may be a top view of the light-emitting element layer EML in the display area DA of the display device 10 as viewed from the top of the display device 10.

Referring to FIG. 3, a second bank BN2 may cover the display area DA, but may expose emission areas EA1, EA2, and EA3 and a pixel-defining layer PDL. Portions of the pixel-defining layer PDL may be exposed between boundaries of the emission areas EA1, EA2, and EA3 and a boundary of the second bank BN2. The exposed pixel-defining layer PDL may be formed to surround the respective emission areas EA1, EA2, and EA3 (e.g., in plan view). Exposed areas of the pixel-defining layer PDL surrounding the emission areas EA1, EA2, and EA3 may have respective widths (e.g., predetermined widths). Some or all of widths d1, d2, and d3 of the exposed areas of the pixel-defining layer PDL surrounding the respective emission areas EA1, EA2, and EA3 may be different from each other.

A plurality of emission areas EA1, EA2, and EA3 may be alternately located. For example, first emission areas EA1, second emission areas EA2, and third emission areas EA3 may be located along the first direction DR1. The first emission areas EA1 and the third emission areas EA3 may be alternately located along the second direction DR2. An arrangement of the emission areas EA1, EA2, and EA3 is not limited to that illustrated in FIG. 3. The emission areas EA1, EA2, and EA3 may also be located in a PenTile™ type, for example, a diamond PenTile™ type (PenTile™ and PENTILE™ being registered trademarks of Samsung Display Co., Ltd., Republic of Korea).

The first to third emission areas EA1, EA2, and EA3 may have different respective areas. For example, an area of the first emission area EA1 may be less than an area of the second emission area EA2, and the area of the second emission area EA2 may be less than an area of the third emission area EA3.

It has been illustrated in FIG. 3 that each of the emission areas EA1, EA2, and EA3 has a round rectangular shape, but each of the emission areas EA1, EA2, and EA3 may have a circular shape or a polygonal shape, such as a triangular shape, a pentagonal shape, or a hexagonal shape. Accordingly, a shape of the exposed pixel-defining layer PDL may also be changed.

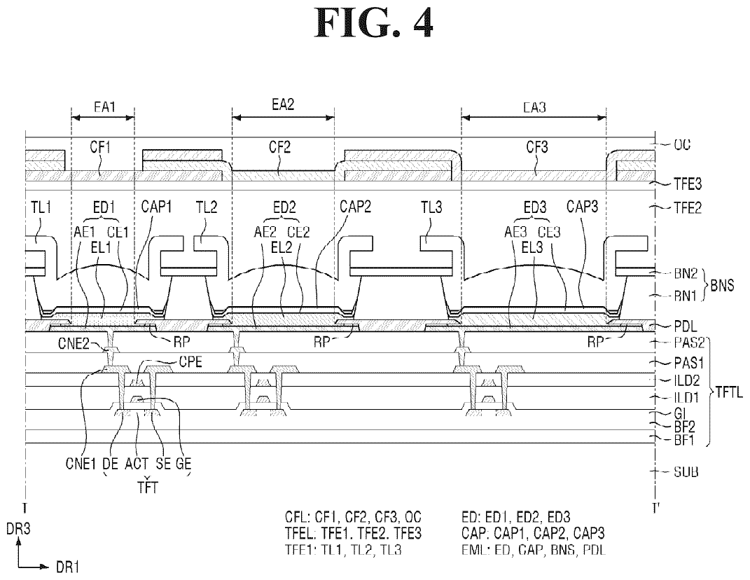

FIG. 4 is a cross-sectional view illustrating a portion of the display device according to one or more embodiments. For example, FIG. 4 is a cross-sectional view taken along the line I-I′ of FIG. 3, and illustrates cross sections of the substrate SUB, the thin film transistor layer TFTL, the light-emitting element layer EML, the thin film encapsulation layer TFEL, and the color filter layer CFL.

The thin film transistor layer TFTL may include a first buffer layer BF1, a second buffer layer BF2, thin film transistors TFT, a gate-insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be located on the substrate SUB. The first buffer layer BF1 may include an inorganic film capable of reducing or preventing permeation of air or moisture. For example, the first buffer layer BF1 may include a plurality of inorganic films that are alternately stacked.

The second buffer layer BF2 may cover the first buffer layer BF1. The second buffer layer BF2 may include an inorganic film capable of reducing or preventing permeation of air or moisture. For example, the second buffer layer BF2 may include a plurality of inorganic films that are alternately stacked.

The thin film transistor TFT may be located on the second buffer layer BF2, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the gate electrode GE in the thickness direction DR3, and may be insulated from the gate electrode GE by the gate-insulating layer GI. A material of the semiconductor layer ACT in portions of the semiconductor layer ACT may become conductors to form the source electrode SE and the drain electrode DE.

The gate electrode GE may be located on the gate-insulating layer GI. The gate electrode GE may overlap the semiconductor layer ACT in the thickness direction DR3 with the gate-insulating layer GI interposed therebetween.

The gate-insulating layer GI may be located on the semiconductor layer ACT. For example, the gate-insulating layer GI may cover the semiconductor layer ACT and the second buffer layer BF2, and may insulate the semiconductor layer ACT and the gate electrode GE from each other. The gate-insulating layer GI may include contact holes through which the first connection electrodes CNE1 penetrate.

The first interlayer insulating layer ILD1 may cover the gate electrode GE and the gate-insulating layer GI. The first interlayer insulating layer ILD1 may include contact holes through which the first connection electrodes CNE1 penetrate. The contact holes of the first interlayer insulating layer ILD1 may be connected to the contact holes of the gate-insulating layer GI and contact holes of the second interlayer insulating layer ILD2.

The capacitor electrodes CPE may be located on the first interlayer insulating layer ILD1. The capacitor electrode CPE may overlap the gate electrode GE in the thickness direction DR3. The capacitor electrode CPE and the gate electrode GE may form capacitance/a capacitor.

The second interlayer insulating layer ILD2 may cover the capacitor electrodes CPE and the first interlayer insulating layer ILD1. The second interlayer insulating layer ILD2 may include contact holes through which the first connection electrodes CNE1 penetrate. The contact holes of the second interlayer insulating layer ILD2 may be connected to the contact holes of the first interlayer insulating layer ILD1 and the contact holes of the gate-insulating layer GI.

The first connection electrodes CNE1 may be located on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer ILD2, the first interlayer insulating layer ILD1, and the gate-insulating layer GI to contact the drain electrode DE of the thin film transistor TFT.

The first passivation layer PAS1 may cover the first connection electrodes CNE1 and the second interlayer insulating layer ILD2. The first passivation layer PAS1 may protect the thin film transistors TFT. The first passivation layer PAS1 may include contact holes through which the second connection electrodes CNE2 penetrate.

The second connection electrodes CNE2 may be located on the first passivation layer PAS1. The second connection electrodes CNE2 may respectively electrically connect the first connection electrodes CNE1 and pixel electrodes AE1, AE2, and AE3 of light-emitting elements ED to each other. The second connection electrode CNE2 may be inserted into the contact hole formed in the first passivation layer PAS1 to contact the first connection electrode CNE1.

The second passivation layer PAS2 may cover the second connection electrodes CNE2 and the first passivation layer PAS1. The second passivation layer PAS2 may include contact holes through which the pixel electrodes AE1, AE2, and AE3 of the light-emitting elements ED penetrate.

The light-emitting element layer EML may be located on the thin film transistor layer TFTL. The light-emitting element layer EML may include the light-emitting elements ED, a pixel-defining layer PDL, capping layers CAP, and a bank structure BNS. The light-emitting elements ED may include the pixel electrodes AE1, AE2, and AE3, light-emitting layers EL1, EL2, and EL3, and common electrodes CE1, CE2, and CE3.

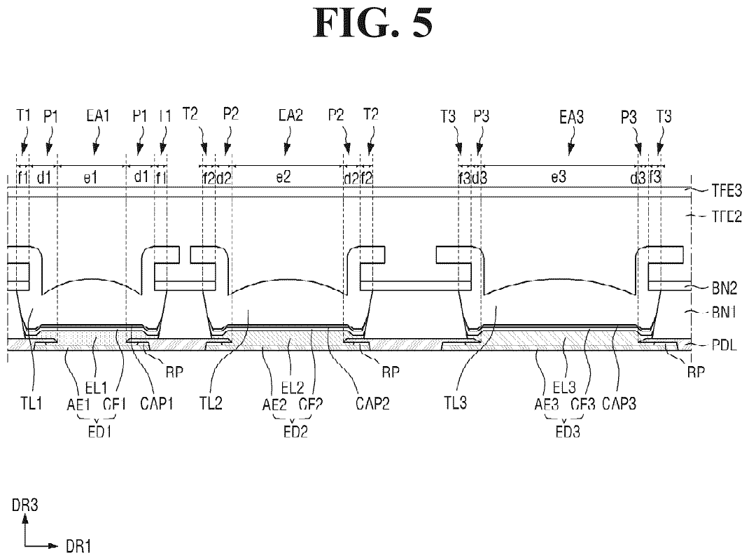

FIG. 5 is a cross-sectional view illustrating a light-emitting element layer EML and a thin film encapsulation layer TFEL in the display area DA of the display device according to one or more embodiments. For example, FIG. 5 is a cross-sectional view illustrating the light-emitting element layer EML and the thin film encapsulation layer TFEL of the first to third emission areas EA1, EA2, and EA3 of FIG. 4.

Referring to FIGS. 4 and 5, the display device 10 may include a plurality of emission areas EA1, EA2, and EA3 located in the display area DA. The emission area EA1, EA2, and EA3 may be defined areas where the pixel electrodes AE1, AE2, and AE3, the light-emitting layer EL1, EL2, and EL3, and the common electrode CE1, CE2, and CE3 respectively overlap each other in the thickness direction of the substrate SUB. The emission areas EA1, EA2, and EA3 may include areas where light is emitted from the light-emitting elements ED1, ED2, and ED3 in which the pixel electrodes AE1, AE2, and AE3, the light-emitting layers EL1, EL2, and EL3, and the common electrodes CE1, CE2, and CE3 are sequentially stacked, respectively, and passes to the color filter layer CFL in the third direction DR3. The emission areas EA1, EA2, and EA3 may include first emission areas EA1, second emission areas EA2, and third emission areas EA3 that are spaced apart from each other, and that emit light of the same color or of different respective colors.

In one or more embodiments, areas or sizes of the first to third emission areas EA1, EA2, and EA3 may be the same as or different from each other. For example, in the display device 10, the first emission area EA1, the second emission area EA2, and the third emission area EA3 may have different areas. However, the present disclosure is not limited thereto. An area of the third emission area EA3 may be greater than areas of the first emission area EA1 and the second emission area EA2, and an area of the second emission area EA2 may be greater than an area of the first emission area EA1. Intensities of the light emitted from the emission areas EA1, EA2, and EA3 may be changed depending on the areas of the emission areas EA1, EA2, and EA3, and a color feeling of a screen displayed on the display device 10 may be controlled by adjusting the areas of the emission area EA1, EA2, and EA3.

In the display device 10, one first emission area EA1, one second emission area EA2, and one third emission area EA3 located adjacent to each other may form one pixel group. One pixel group may include the emission areas EA1, EA2, and EA3 emitting light of different respective colors to express a white gradation. However, the present disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and the like.

The display device 10 may include a plurality of light-emitting elements ED1, ED2, and ED3 located in different emission areas EA1, EA2, and EA3. The light-emitting elements ED1, ED2, and ED3 may include a first light-emitting element ED1 located in the first emission area EA1, a second light-emitting element ED2 located in the second emission area EA2, and a third light-emitting element ED3 located in the third emission area EA3.

The light-emitting elements ED1, ED2, and ED3 may include pixel electrodes AE1, AE2, and AE3, light-emitting layers EL1, EL2, and EL3, and common electrodes CE1, CE2, and CE3, respectively, and the light-emitting elements ED1, ED2, and ED3 located in the different emission areas EA1, EA2, and EA3 may emit light of different respective colors depending on materials of the light-emitting layers EL1, EL2, and EL3. For example, the first light-emitting element ED1 located in the first emission area EA1 may emit green light having a peak wavelength in the range of about 510 nm to about 550 nm, the second light-emitting element ED2 located in the second emission area EA2 may emit red light having a peak wavelength in the range of about 610 nm to about 650 nm, and the third light-emitting element ED3 located in the third emission area EA3 may emit blue light having a peak wavelength in the range of about 440 nm to about 480 nm. The first to third emission areas EA1, EA2, and EA3 constituting one pixel may include the light-emitting elements ED1, ED2, and ED3 emitting the light of the different colors to express a white gradation. Alternatively, the light-emitting layers EL1, EL2, and EL3 may include two or more materials for emitting the light of the different colors, such that one light-emitting layer may emit mixed light. For example, the light-emitting layers EL1, EL2, and EL3 may include both of a red light-emitting material and a green light-emitting material to emit yellow light, or may include all of a red light-emitting material, a green light-emitting material, and a blue light-emitting material to emit white light.

The pixel electrodes AE1, AE2, and AE3 may be located on the second passivation layer PAS2. The pixel electrodes AE1, AE2, and AE3 may be located in the plurality of emission areas EA1, EA2, and EA3, respectively. The pixel electrodes AE1, AE2, and AE3 may include a first pixel electrode AE1 located in the first emission area EA1, a second pixel electrode AE2 located in the second emission area EA2, and a third pixel electrode AE3 located in the third emission area EA3. The first pixel electrode AE1, the second pixel electrode AE2, and the third pixel electrode AE3 may be spaced apart from each other on the second passivation layer PAS2.

The pixel electrodes AE1, AE2, and AE3 may be respectively electrically connected to the drain electrodes DE of the thin film transistors TFT through the first and second connection electrodes CNE1 and CNE2. Edges of the pixel electrodes AE1, AE2, and AE3 spaced apart from each other are covered by the pixel-defining layer PDL, such that the first to third pixel electrodes AE1, AE2, and AE3 may be insulated from each other.

The pixel electrodes AE1, AE2, and AE3 may include a transparent electrode material and/or a conductive metal material, and may have a single-layer or multilayer structure. The conductive metal material may be one or more of silver (Ag), copper (Cu), aluminum (AI), nickel (Ni), lanthanum (La), titanium (Ti), or titanium nitride (TiN). The transparent electrode material may be one or more of indium tin oxide (ITO), indium zinc oxide (IZO), or indium tin zinc oxide (ITZO).

The light-emitting layers EL1, EL2, and EL3 may be located on the pixel electrodes AE1, AE2, and AE3, respectively. The light-emitting layers EL1, EL2, and EL3 may be organic light-emitting layers made of an organic material, and may be formed on the pixel electrodes AE1, AE2, and AE3, respectively, through a deposition process. The light-emitting layers EL1, EL2, and EL3 may have a multilayer structure, and a hole injection material, a hole-transporting material, a light-emitting material, an electron-transporting material, and/or an electron injection material may constitute layers of the light-emitting layers EL1, EL2, and EL3, respectively. When the thin film transistors TFT apply voltages (e.g., predetermined voltages) to the pixel electrodes AE1, AE2, and AE3 of the light-emitting elements ED1, ED2, and ED3, and when the common electrodes CE1, CE2, and CE3 of the light-emitting elements ED1, ED2, and ED3 receive a common voltage or a cathode voltage, holes and electrons may be injected and transported, respectively, and may combine with each other in the light-emitting layers EL1, EL2, and EL3 to emit light.

The light-emitting layers EL1, EL2, and EL3 may include a first light-emitting layer EL1, a second light-emitting layer EL2, and a third light-emitting layer EL3 respectively located in the different emission areas EA1, EA2, and EA3. The first light-emitting layer EL1 may be located on the first pixel electrode AE1 in the first emission area EA1, the second light-emitting layer EL2 may be located on the second pixel electrode AE2 in the second emission area EA2, and the third light-emitting layer EL3 may be located on the third pixel electrode AE3 in the third emission area EA3. A plurality of light-emitting layers EL1, EL2, and EL3 may emit light of different colors, respectively, or one light-emitting layer EL1, EL2, or EL3 may emit mixed light. In one or more embodiments, the first light-emitting layer EL1 may emit green light, the second light-emitting layer EL2 may emit red light, and the third light-emitting layer EL3 may emit blue light.

The light-emitting layers EL1, EL2, and EL3 may be located on an upper surface of the pixel-defining layer PDL. In one or more embodiments, side surfaces of residual patterns RP may be depressed, as compared to side surfaces of the pixel-defining layer PDL, and portions of the light-emitting layers EL1, EL2, and EL3 may be located in spaces between the pixel electrodes AE1, AE2, and AE3 and the pixel-defining layer PDL. In one or more embodiments, the light-emitting layers EL1, EL2, and EL3 may contact the pixel-defining layer PDL, the residual patterns RP, and the pixel electrodes AE1, AE2, and AE3.

The common electrodes CE1, CE2, and CE3 may be located on the light-emitting layers EL1, EL2, and EL3, respectively. The common electrodes CE1, CE2, and CE3 may include a transparent conductive material to emit the light generated from the light-emitting layers EL1, EL2, and EL3. The common electrodes CE1, CE2, and CE3 may receive a common voltage or a low potential voltage. When the pixel electrodes AE1, AE2, and AE3 receive voltages corresponding to data voltages, and when the common electrodes CE1, CE2, and CE3 receive the low potential voltage, respective potential differences are formed between the pixel electrodes AE1, AE2, and AE3 and the common electrodes CE1, CE2, and CE3, such that the light-emitting layers EL1, EL2, and EL3 may emit the light.

The common electrodes CE1, CE2, and CE3 may include a first common electrode CE1, a second common electrode CE2, and a third common electrode CE3 respectively located in the different emission areas EA1, EA2, and EA3. The first common electrode CE1 may be located on the first light-emitting layer EL1 in the first emission area EA1, the second common electrode CE2 may be located on the second light-emitting layer EL2 in the second emission area EA2, and the third common electrode CE3 may be located on the third light-emitting layer EL3 in the third emission area EA3. The first to third common electrodes CE1, CE2, and CE3 may be spaced apart from each other.

Capping layers CAP1, CAP2, and CAP3 may be located on the common electrodes CE1, CE2, and CE3, respectively. The capping layers CAP1, CAP2, and CAP3 may include an organic or inorganic insulating material and cover patterns located on the light-emitting elements ED1, ED2, and ED3. The capping layers CAP1, CAP2, and CAP3 may reduce or prevent damage to the light-emitting elements ED1, ED2, and ED3 due to external air. In one or more embodiments, each of the capping layers CAP1, CAP2, and CAP3 may include an organic material, such as α-NPD, NPB, TPD, m-MTDATA, Alq₃, LiF, and/or CuPc, or an inorganic material, such as aluminum oxide, titanium oxide, tantalum oxide, hafnium oxide, zinc oxide, silicon oxide, silicon nitride, and/or silicon oxynitride.

The capping layers CAP1, CAP2, and CAP3 may include a first capping layer CAP1, a second capping layer CAP2, and a third capping layer CAP3 respectively located in the different emission areas EA1, EA2, and EA3. The first to third capping layers CAP1, CAP2, and CAP3 may be spaced apart from each other.

The pixel-defining layer PDL may be located on the second passivation layer PAS2, but may expose upper surfaces of the pixel electrodes AE1, AE2, and AE3 to define the emission areas EA1, EA2, and EA3. The pixel-defining layer PDL may have first side surfaces defining the emission areas EA1, EA2, and EA3, and the first side surfaces may be distinguished from second side surfaces of the pixel-defining layer PDL facing side surfaces of the pixel electrodes AE1, AE2, and AE3.

The pixel-defining layer PDL may include an inorganic insulating material. The pixel-defining layer PDL may include at least one of silicon nitride, silicon oxynitride, silicon oxide, titanium oxide, aluminum oxide, tantalum oxide, hafnium oxide, zinc oxide, or amorphous silicon, but is not limited thereto.

According to one or more embodiments, the pixel-defining layer PDL may be located on the edges of the pixel electrodes AE1, AE2, and AE3, but may be spaced apart from the upper surfaces of the pixel electrodes AE1, AE2, and AE3. The pixel-defining layer PDL may not directly contact the upper surfaces of the pixel electrodes AE1, AE2, and AE3 while partially overlapping the upper surfaces of the pixel electrodes AE1, AE2, and AE3 in the thickness direction DR3 of the substrate SUB, and the residual patterns RP may be located between the pixel-defining layer PDL and the pixel electrodes AE1, AE2, and AE3. However, the pixel-defining layer PDL may directly contact the side surfaces of the pixel electrodes AE1, AE2, and AE3. The side surfaces of the pixel-defining layer PDL may protrude more than side surfaces of the second bank BN2 toward the emission areas EA1, EA2, and EA3.

The residual patterns RP may be located on the edges of the pixel electrodes AE1, AE2, and AE3, respectively. The pixel-defining layer PDL may not directly contact the upper surfaces of the pixel electrodes AE1, AE2, and AE3 due to the residual patterns RP. The residual patterns RP may be formed by removing portions of sacrificial layers located on the pixel electrodes AE1, AE2, and AE3 in processes of manufacturing the display device 10. The residual patterns RP may include a metal or an oxide semiconductor material. Only a case where side surfaces of the residual patterns RP toward the emission areas EA1, EA2, and EA3 are depressed compared to the first side surfaces of the pixel-defining layer PDL has been illustrated in FIGS. 4 and 5, but the present disclosure is not limited thereto. The side surfaces of the residual patterns RP may protrude more than the first side surfaces of the pixel-defining layer PDL toward the emission areas EA1, EA2, and EA3, or may be aligned with the first side surfaces of the pixel-defining layer PDL.

The display device 10 may include a plurality of bank structures BNS located on the pixel-defining layer PDL. The bank structure BNS may have a structure in which banks BN1 and BN2 including different respective materials are sequentially stacked, may include/define a plurality of openings including the emission areas EA1, EA2, and EA3, and may overlap light-blocking areas of color filters CF1, CF2, and CF3 to be described later.

A first bank BN1 may be located on the pixel-defining layer PDL. Side surfaces of the first bank BN1 may be depressed more than the first side surfaces of the pixel-defining layer PDL opposite to a direction toward the emission areas EA1, EA2, and EA3. The side surfaces of the first bank BN1 may be depressed more than side surfaces of a second bank BN2 (to be described later) in the direction opposite to the direction toward the emission areas EA1, EA2, and EA3.

According to one or more embodiments, the first bank BN1 may include a metal material. In one or more embodiments, the first bank BN1 may include aluminum (Al), oxide of aluminum (Al), or an alloy of aluminum (Al).

The common electrodes CE1, CE2, and CE3 may directly contact the side surfaces of the first bank BN1. First and second ends of the common electrodes CE1, CE2, and CE3 may contact the side surfaces of the first bank BN1. The common electrodes CE1, CE2, and CE3 of different light-emitting elements ED1, ED2, and ED3 may directly contact the first bank BN1, respectively, and the first bank BN1 may include a conductive material, such that the common electrodes CE1, CE2, and CE3 may be electrically connected to each other through the first bank BN1.

According to one or more embodiments, the light-emitting layers EL1, EL2, and EL3 may directly contact the side surfaces of the first bank BN1. Contact areas between the common electrodes CE1, CE2, and CE3 and the side surfaces of the first bank BN1 may be greater than contact areas between the light-emitting layers EL1, EL2, and EL3 and the side surfaces of the first bank BN1. The common electrodes CE1, CE2, and CE3 may have a greater area than the light-emitting layers EL1, EL2, and EL3 contacting the side surfaces of the first bank BN1, or may be present up to a greater height than the light-emitting layers EL1, EL2, and EL3 on the side surfaces of the first bank BN1. Because the common electrodes CE1, CE2, and CE3 of the different light-emitting elements ED1, ED2, and ED3 are electrically connected to each other through the first bank BN1, it may be suitable that the common electrodes CE1, CE2, and CE3 contact the first bank BN1 in a greater area, or to a greater degree.

The first bank BN1 may have an upper surface at a higher position than the common electrodes CE1, CE2, and CE3 and the capping layers CAP1, CAP2, and CAP3. A height from the substrate SUB to the upper surface of the first bank BN1 may be greater than a height from the substrate SUB to the common electrodes CE1, CE2, and CE3.

The second bank BN2 may be located on the first bank BN1. The second bank BN2 may define openings overlapping the respective emission areas EA1, EA2, and EA3. Each of the openings may include side surfaces. The second bank BN2 may include tips or eaves, which are areas protruding compared to the first bank BN1. The side surfaces of the second bank BN2 may protrude more than the side surfaces of the first bank BN1 toward the emission areas EA1, EA2, and EA3.

The second bank BN2 have a shape in which their side surfaces protrude more than the side surfaces of the first bank BN1 toward the emission areas EA1, EA2, and EA3, and accordingly, undercut structures of the first bank BN1 may be formed under the tips T1, T2, and T3 of the second bank BN2.

In the display device 10 according to one or more embodiments, the bank structure BNS includes the tips T1, T2, and T3 protruding toward the emission areas EA1, EA2, and EA3, and thus, the light-emitting layers EL1, EL2, and EL3 and the common electrodes CE1, CE2, and CE3 spaced apart from each other may be formed through deposition and etching processes rather than a mask process. In addition, it is possible to form different layers individually in the different emission areas EA1, EA2, and EA3 even through a deposition process. For example, even though the light-emitting layers EL1, EL2, and EL3 and the common electrodes CE1, CE2, and CE3 of the light-emitting elements ED1, ED2, and ED3 are formed through a deposition process that does not use a mask, deposited materials may be disconnected from each other with the bank structure BNS interposed therebetween by the tips T1, T2, and T3 of the second bank BN2 rather than being connected to each other between the emission areas EA1, EA2, and EA3. It is possible to form the different layers individually in the different emission areas EA1, EA2, and EA3 through a process of forming a material for forming a corresponding layer on the entire surface of the display device 10, and then etching and removing a layer formed in unwanted areas. In the display device 10, through the deposition and etching processes excluding a mask process, the different light-emitting elements ED1, ED2, and ED3 may be formed for each of the emission areas EA1, EA2, and EA3, an unnecessary component may be omitted from the display device 10, and an area of the non-display area NDA may be reduced or minimized.

The second bank BN2 may include a metal material that is different from the metal material of the first bank BN1. The metal material of the second bank BN2 may be any material that is removed along with the metal material of the first bank BN1 by dry etching, but that has an etch rate that is relatively much lower than that of the first bank BN1 or that is not etched with respect to wet etching. In one or more embodiments, the first bank BN1 includes aluminum (Al), oxide of aluminum (Al), or an alloy of aluminum (Al), and the second bank BN2 may include titanium (Ti), oxide of titanium (Ti), or an alloy of titanium (Ti).

The second bank BN2 may include a first tip T1 of an area surrounding the first emission area EA1, a second tip T2 of an area surrounding the second emission area EA2, and a third tip T3 of an area surrounding the third emission area EA3. Respective widths f1, f2, and f3 of the first to third tips T1, T2, and T3 may be defined as distances between the side surfaces of the second bank BN2 and the side surfaces of the first bank BN1 that are adjacent to the respective emission areas EA1, EA2, and EA3, and may be measured on a lower surface of the second bank BN2. For example, the width f1 of the first tip T1 may be a distance between the side surface of the second bank BN2 and the side surface of the first bank BN1 on the lower surface of the second bank BN2. When all of the first to third tips T1, T2, and T3 are formed in one process, the first to third tips T1, T2, and T3 may respectively have widths f1, f2, and f3 that are the same as each other. By adjusting a process of wet-etching the side surfaces of the first bank BN1, the widths f1, f2, and f3 of the first to third tips T1, T2, and T3 may be adjusted. The tips T1, T2, and T3 of the second bank BN2 may overlap the common electrodes CE1, CE2, and CE3, the light-emitting layer EL1, EL2, and EL3, and/or the pixel-defining layer PDL in a direction DR3 that is substantially perpendicular to the substrate SUB. In the present specification, several values within a range may be said to be the same as each other.

The second bank BN2 may overlap some areas of the pixel-defining layer PDL in the thickness direction DR3 of the substrate SUB, and may not overlap some other areas of the pixel-defining layer PDL. Areas P1, P2, and P3 where the pixel-defining layer PDL does not overlap the second bank BN2 to be exposed may be the pixel-defining layer PDL illustrated in FIG. 3.

The pixel-defining layer PDL may include a first exposed portion P1 adjacent to the first emission area EA1 and surrounding the first emission area EA1, a second exposed portion P2 adjacent to the second emission area EA2 and surrounding the second emission area EA2, and a third exposed portion P3 adjacent to the third emission area EA3 and surrounding the third emission area EA3. Widths d1, d2, and d3 of the first to third exposed portions P1, P2, and P3 may be defined as the widths of the exposed areas of the pixel-defining layer PDL surrounding the respective emission areas EA1, EA2, and EA3 in the top view as illustrated in FIG. 3, or as distances between the side surfaces of the second bank BN2 and the first side surfaces of the pixel-defining layer PDL that are adjacent to the respective emission areas EA1, EA2, and EA3 in the cross-sectional view as illustrated in FIG. 4. For example, the width d1 of the first exposed portion P1 may be the distance between the first side surface of the pixel-defining layer PDL and the side surface of the second bank BN2 that are adjacent to the first emission area EA1, and may be a distance between the first tip T1 and the first emission area EA1.

The width d1 of the first exposed portion P1 may be greater than the width d2 of the second exposed portion P2. The width d2 of the second exposed portion P2 may be greater than the width d3 of the third exposed portion P3. The width d3 of the third exposed portion P3 may be less than the width d1 of the first exposed portion P1. An area of the first emission area EA1 may be smaller than an area of the second emission area EA2. It has been illustrated in FIG. 5 that a width e1 of the first emission area EA1 is less than a width e2 of the second emission area EA2, and that the width e2 of the second emission area EA2 is less than a width e3 of the third emission area EA3, but a size comparison between the widths e1, e2, and e3 of the emission areas EA1, EA2, and EA3 may be changed depending on a cutting direction.

Meanwhile, the light-emitting layers EL1, EL2, and EL3 are entirely deposited on the substrate SUB, but depending on a deposition angle, deposition thicknesses of the light-emitting layers EL1, EL2, and EL3 may become small, or deposition of the light-emitting layers EL1, EL2, and EL3 may be non-uniform, at edge areas of the emission areas EA1, EA2, and EA3.

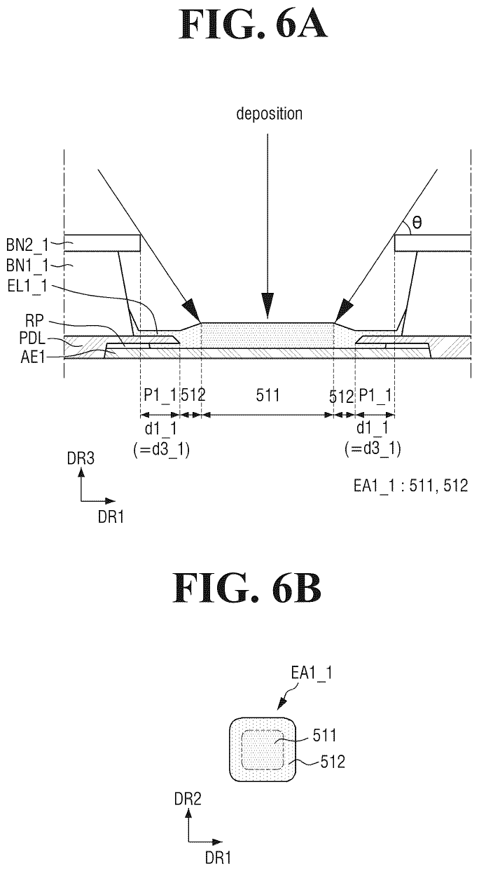

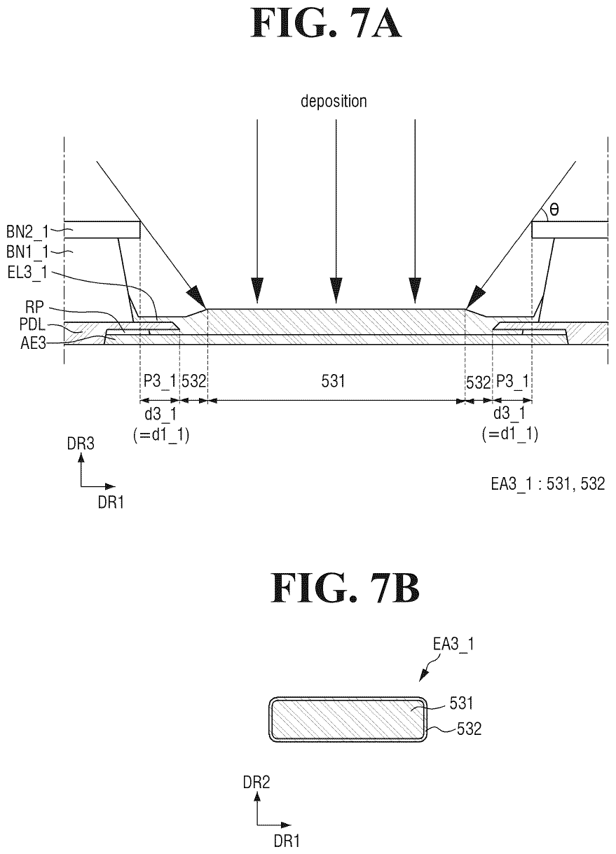

FIGS. 6A and 7A and FIGS. 6B and 7B are, respectively, cross-sectional views illustrating substantially uniform deposition and non-uniform deposition of light-emitting layers EL1_1 and EL3_1 when widths d1_1 and d3_1 of exposed portions P1_1 and P3_1 of a pixel-defining layer PDL are the same as each other, and top views of emission areas EA1_1 and EA3_1. FIGS. 6A to 7B illustrate a case where the exposed portions P1_1 and P3_1 of the pixel-defining layer PDL are not designed differently and have the same width, according to the emission areas EA1_1 and EA3_1 having different areas.

FIG. 6A is a cross-sectional view illustrating deposition of a first light-emitting layer EL1_1 in a first emission area EA1_1 having a relatively small area, and FIG. 6B is a top view illustrating a substantially uniformly deposited area 511 and a non-uniformly deposited area 512 in the first emission area EA1_1.

FIG. 7A is a cross-sectional view illustrating deposition of a third light-emitting layer EL3_1 in a third emission area EA3_1 having a relatively large area, and FIG. 7B is a top view illustrating a substantially uniformly deposited area 531 and a non-uniformly deposited area 532 in the third emission area EA3_1.

Referring to FIGS. 6A and 7A, first areas 511 and 531, in which the light-emitting layers EL1_1 and EL3_1 are substantially uniformly deposited, are located near the centers of areas overlapping the openings of the second bank BN2. The first areas 511 and 531 may be defined as areas having thicknesses of about 95% or more of thicknesses of the light-emitting layers EL1_1 and EL3_1 at points where the thicknesses of the light-emitting layers EL1_1 and EL3_1 are greatest, and may be normal emission areas. Second areas 512 and 532 may be located around the first areas 511 and 531. The second areas 512 and 532 may be defined as areas having thicknesses less than about 95% of the thicknesses of the light-emitting layers EL1_1 and EL3_1 at the points where the thicknesses of the light-emitting layers EL1_1 and EL3_1 are greatest, and may be abnormal emission areas. When the light-emitting layers EL1_1 and EL3_1 are deposited, the light-emitting layers EL1_1 and EL3_1 may not be sufficiently deposited within the emission areas EA1_1 and EA3_1 due to shadow effects of the tips T1 and T3 of the second bank BN2 as well as in areas overlapping the tips T1 and T3 of the second bank BN2, and there may be second areas 512 and 532 where the deposition is non-uniform. In the second areas 512 and 532, the thicknesses of the light-emitting layers EL1_1 and EL3_1 may be reduced. A deposition angle θ may be changed depending on a position of the substrate SUB, and the second areas 512 and 532 may be enlarged or reduced.

The shadow effect in the first emission area EA1_1 is greater than that in the third emission area EA3_1. Even though the widths d1_1 and d3_1 of the second areas 512 and 532 are the same as each other, a ratio of the second area 512 in the first emission area EA1_1 having a small area may be much greater than that in the third emission area EA3_1 (see FIGS. 6B and 7B). It may be difficult to secure a relatively large first area 511 in the first emission area EA1_1 having the relatively small area.

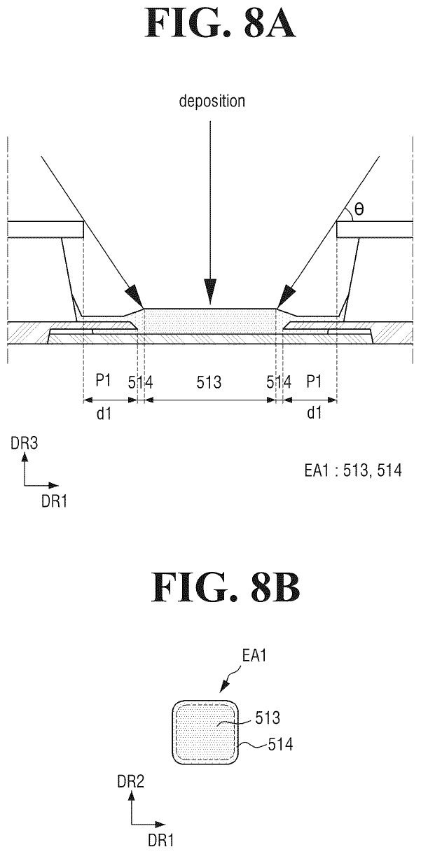

On the other hand, when some of the exposed portions P1, P2, and P3 of the pixel-defining layer PDL are designed differently depending on the emission areas EA1, EA2, and EA3 to have different widths, the first emission area EA1 having a small area may also have a first area 513 where the deposition is substantially uniform, as shown in FIG. 8A.

FIGS. 8A and 8B are, respectively, a cross-sectional view illustrating substantially uniform deposition and non-uniform deposition of a light-emitting layer EL1 of the display device 10 according to one or more embodiments, and a top view of an emission area EA1.

When the width d1 of the first exposed portion P1 of the pixel-defining layer PDL adjacent to the first emission area EA1 having the relatively small area is increased (d1>d1_1), a first area 513 in the first emission area EA1 increases, and a second area 514 in the first emission area EA1 decreases. Referring to FIG. 8B, it can be seen that a ratio of the first area 513 within the first emission area EA1 has significantly increased. In one or more embodiments, an area of the first area 513 of each of the light-emitting layers EL1, EL2, and EL3 may be about 50% or more, about 70% or more, or about 80% or more of an area of each of the emission areas EA1, EA2, and EA3. Stable light-emitting elements ED1, ED2, and ED3 may be manufactured in the display device 10 having high resolution. The display device 10 or the display panel 100 according to one or more embodiments may have a resolution of about 1500 pixels per inch (ppi) or more.

A width of an area where the pixel-defining layer PDL and the first light-emitting layer EL1 overlap each other in the thickness direction DR3 of the substrate SUB may be greater than a width of an area where the pixel-defining layer PDL and the second light-emitting layer EL2 overlap each other. The width of the area where the pixel-defining layer PDL and the second light-emitting layer EL2 overlap each other may be greater than a width of an area where the pixel-defining layer PDL and the third light-emitting layer EL3 overlap each other. The area where the pixel-defining layer PDL and the first light-emitting layer EL1 overlap each other may include the first exposed portion P1 of the pixel-defining layer PDL, and may be greater than the first exposed portion P1.

The shadow effects during the deposition of the light-emitting layer EL1, EL2, and EL3 and the exposed portions P1, P2, and P3 of the pixel-defining layer PDL have been described with reference to FIGS. 6A to 8B, but the same description as the description of the shadow effects and the exposed portions P1, P2, and P3 of the pixel-defining layer PDL may be applied to deposition of the common electrodes CE1, CE2, and CE3. In one or more embodiments, an area of a first area 513 of each of the common electrodes CE1, CE2, and CE3 may be 50% or more, 70% or more, or 80% or more of the area of each of the emission areas EA1, EA2, and EA3. A thickness of each of the common electrodes CE1, CE2, and CE3 in a second area may be reduced.

The pixel-defining layer PDL adjacent to the second emission area EA2 and the third emission area EA3, which have relatively large areas, may have the second exposed portion P2 and the third exposed portion P3 that have widths that are less than the width d1 of the first exposed portion P1, such that the common electrodes CE2 and CE3 may have sufficient deposition areas on the side surfaces of the first bank BN1.

The thin film encapsulation layer TFEL may be located on the light-emitting elements ED1, ED2, and ED3 and the bank structure BNS, and may cover the plurality of light-emitting elements ED1, ED2, and ED3 and the bank structure BNS. The thin film encapsulation layer TFEL may include at least one inorganic film to reduce or prevent permeation of oxygen or moisture into the light-emitting element layer EML. The thin film encapsulation layer TFEL may include at least one organic film to protect the light-emitting element layer EML from foreign substances, such as dust.

In one or more embodiments, the thin film encapsulation layer TFEL may include a lower inorganic encapsulation layer TFE1, an organic encapsulation layer TFE2, and an upper inorganic encapsulation layer TFE3 that are sequentially stacked.

Each of the lower inorganic encapsulation layer TFE1 and the upper inorganic encapsulation layer TFE3 may include one or more inorganic insulating materials. The inorganic insulating material may be any one of silicon oxide, silicon nitride, or silicon oxynitride, and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy-based resin, polyimide, polyethylene, or the like. For example, the organic encapsulation layer TFE2 may include an acrylic resin, such as polymethyl methacrylate or polyacrylic acid. The organic encapsulation layer TFE2 may be formed by curing a monomer or applying a polymer.

The lower inorganic encapsulation layer TFE1 may be located on the light-emitting elements ED1, ED2, and ED3 and the bank structure BNS. The lower encapsulation layer TFE1 may include a first inorganic layer TL1, a second inorganic layer TL2, and a third inorganic layer TL3 respectively corresponding to the different emission areas EA1, EA2, and EA3. The first inorganic layer TL1, the second inorganic layer TL2, and the third inorganic layer TL3 may include an inorganic insulating material, and may cover the light-emitting elements ED1, ED2, and ED3, respectively. The first inorganic layer TL1, the second inorganic layer TL2, and the third inorganic layer TL3 may reduce or prevent damage to the light-emitting elements ED1, ED2, and ED3 due to external air.

The lower inorganic encapsulation layers TFE1: TL1, TL2, and TL3 may be formed through chemical vapor deposition (CVD), and may thus be formed along steps of layers on which they are deposited. For example, the first inorganic layer TL1, the second inorganic layer TL2, and the third inorganic layer TL3 may form thin films even under undercuts by the tips of the bank structure BNS. The lower inorganic encapsulation layers TL1, TL2, and TL3 may be located along an upper surface, the side surfaces, and a lower surface of the second bank BN2, the side surfaces of the first bank BN1, and upper surfaces of the common electrodes CE1, CE2, and CE3. The lower inorganic encapsulation layers TL1, TL2, and TL3 may contact the lower surface of the second bank BN2 to reduce or prevent moisture permeation from external air.

The first inorganic layer TL1 may not overlap the second light-emitting element ED2 and the third light-emitting element ED3, and may be located only on the first light-emitting element ED1 and the bank structure BNS around the first light-emitting element ED1. The second inorganic layer TL2 may not overlap the first light-emitting element ED1 and the third light-emitting element ED3, and may be located only on the second light-emitting element ED2 and the bank structure BNS around the second light-emitting element ED2. The third inorganic layer TL3 may not overlap the first light-emitting element ED1 and the second light-emitting element ED2, and may be located only on the third light-emitting element ED3 and the bank structure BNS around the third light-emitting element ED3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be spaced apart from each other on the bank structure BNS.

The lower inorganic encapsulation layers TL1, TL2, and TL3 may be respectively located on the light-emitting elements ED1, ED2, and ED3 and the upper surface and the lower surface of the second bank BN2 around the light-emitting elements ED1, ED2, and ED3, but may be spaced apart from the upper surface of the second bank BN2. That is, each of the lower inorganic encapsulation layers TL1, TL2, and TL3 may have an undercut structure on the second bank BN2. Spaces between the lower inorganic encapsulation layers TL1, TL2, and TL3 and the upper surface of the second bank BN2 spaced apart from each other may be spaces where materials of the light-emitting layers EL1, EL2, and EL3 and the common electrodes CE1, CE2, and CE3 that are entirely deposited are removed.

The organic encapsulation layer TFE2 is located on the second bank BN2 and the lower inorganic encapsulation layers TL1, TL2, and TL3. Portions of the organic encapsulation layer TFE2 may be located in the spaces between the lower inorganic encapsulation layers TL1, TL2, and TL3 and the upper surface of the second bank BN2 spaced apart from each other. In areas where the second bank BN2 and the lower inorganic encapsulation layers TL1, TL2, and TL3 overlap each other, the second bank BN2, the organic encapsulation layer TFE2, and the lower inorganic encapsulation layers TL1, TL2, and TL3 may be sequentially located. In areas of the tips T1, T2, and T3, the organic encapsulation layer TFE2 and the lower inorganic encapsulation layers TL1, TL2, and TL3 may be sequentially located on the second bank BN2, and the organic encapsulation layer TFE2 may be located again on the lower inorganic encapsulation layers TL1, TL2, and TL3. In other words, portions of the organic encapsulation layer TFE2 may be located between the upper surface of the second bank BN2 and the lower inorganic encapsulation layers TL1, TL2, and TL3 on the tips T1, T2, and T3 of the second bank BN2, and the other portions of the organic encapsulation layer TFE2 may be located on the lower inorganic encapsulation layers TL1, TL2, and TL3.

In one or more embodiments, the entirety of the upper surface of the second bank BN2 may contact the organic encapsulation layer TFE2. First lower surfaces of the lower inorganic encapsulation layers TL1, TL2, and TL3 may be surfaces facing the upper surface of the second bank BN2, and may contact the organic encapsulation layer TFE2. The organic encapsulation layer TFE2 may contact the side surfaces of the second bank BN2.

The upper inorganic encapsulation layer TFE3 may be located on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

In one or more embodiments, a light-blocking layer may be optionally located on the thin film encapsulation layer TFEL. The light-blocking layer may be positioned between the emission areas EA1, EA2, and EA3. The light-blocking layer may include a light-absorbing material. For example, the light-blocking layer may include an inorganic black pigment or an organic black pigment. The inorganic black pigment may be carbon black, and the organic black pigment may include at least one of Lactam Black, Perylene Black, or Aniline Black, but the present disclosure is not limited thereto. The light-blocking layer may reduce or prevent color mixing due to permeation of visible light between the first to third emission areas EA1, EA2, and EA3 to improve a color gamut of the display device 10.

The display device 10 may include a plurality of color filters CF1, CF2, and CF3 respectively located on the emission areas EA1, EA2, and EA3. Each of the plurality of color filters CF1, CF2, and CF3 may include a filtering pattern area and a light-blocking area. The filtering pattern areas may be formed to overlap the emission areas EA1, EA2, and EA3 or the openings of the bank structures BNS, and may form light-emitting areas through which the light emitted from the emission areas EA1, EA2, and EA3 is emitted. The light-blocking areas are areas where the light may not be transmitted because the plurality of color filters CF1, CF2, and CF3 are stacked.

The color filters CF1, CF2, and CF3 may include a first color filter CF1, a second color filter CF2, and a third color filter CF3 respectively corresponding to the different emission areas EA1, EA2, and EA3. The color filters CF1, CF2, and CF3 may include colorants, such as dyes or pigments for absorbing light of wavelength bands other than light of a corresponding wavelength band, and may correspond to the colors of the light-emitting from the emission areas EA1, EA2, and EA3. For example, the first color filter CF1 may be a green color filter overlapping the first emission area EA1 for transmitting only first light, which is the green light, therethrough. The second color filter CF2 may be a red color filter overlapping the second emission area EA2 for transmitting only second light, which is the red light, therethrough, and the third color filter CF3 may be a blue color filter overlapping the third emission area EA3 for transmitting only third light, which is the blue light, therethrough.

In the display device 10, the color filters CF1, CF2, and CF3 overlap each other, and accordingly, an intensity of reflected light by external light may be reduced. Furthermore, a color feeling of the reflected light by the external light may be controlled by adjusting an arrangement, shapes, areas, and the like, of the color filters CF1, CF2, and CF3 in plan view.

An overcoat layer OC may be located on the color filters CF1, CF2, and CF3 to planarize upper ends of the color filters CF1, CF2, and CF3. The overcoat layer OC may be a colorless light-transmitting layer that does not have a color of a visible light band. For example, the overcoat layer OC may include a colorless light-transmitting organic material, such as an acrylic resin.

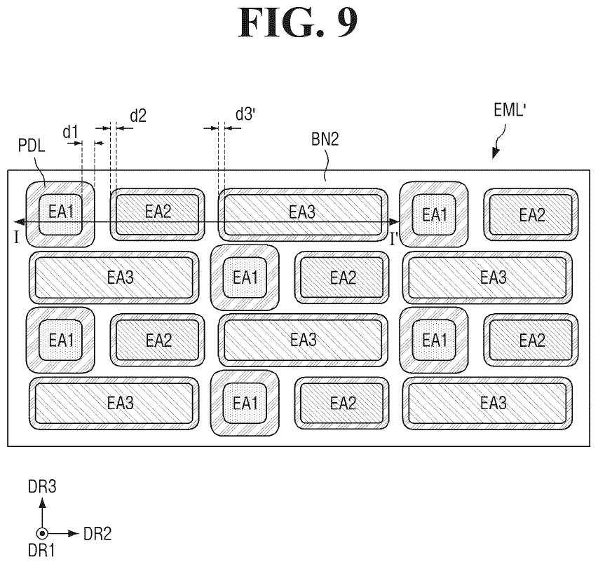

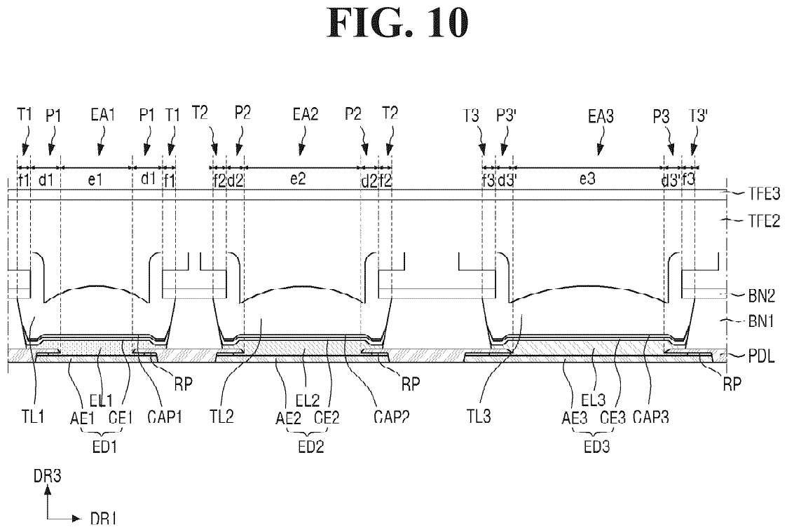

FIG. 9 is a top view of a light-emitting element layer EML′ of a display device 10 according to one or more other embodiments. FIG. 10 is a cross-sectional view illustrating a light-emitting element layer EML′ and a thin film encapsulation layer TFEL of the display device 10 according to one or more other embodiments, and illustrates the light-emitting element layer EML′ and the thin film encapsulation layer TFEL of the display device 10 taken along the line I-I′ of FIG. 9.

One or more other embodiments corresponding to FIGS. 9 and 10 are different from one or more embodiments corresponding to FIGS. 3 and 5 in that a width d3′ of a third exposed portion P3′ of the pixel-defining layer PDL is the same as the width d2 of the second exposed portion P2. The third emission area EA3 may have a greater area than the second emission area EA2, but the widths d3′ and d2 of adjacent exposed portions P3′ and P2 may be the same as each other. Even though the second exposed portion P2 and the third exposed portion P3′ have the same width, the third emission area EA3 has a relatively large area, such that a ratio of the first area in the third emission area EA3 may be great.

The embodiments of the present disclosure have been described hereinabove with reference to the accompanying drawings, but it will be understood by one of ordinary skill in the art to which the present disclosure pertains that various modifications and alterations may be made without departing from the aspects of the present disclosure. Therefore, it is to be understood that the embodiments described above are illustrative rather than being restrictive in all aspects.

1 what is claimed is:

1. A display device comprising:
a substrate comprising a first emission area and a second emission area spaced apart;
a pixel-defining layer comprising side surfaces defining the first emission area and the second emission area;
a first light-emitting element above the substrate in the first emission area, and comprising a first pixel electrode, a first light-emitting layer, and a first common electrode;
a second light-emitting element above the substrate in the second emission area, and comprising a second pixel electrode, a second light-emitting layer, and a second common electrode;
a first bank above the pixel-defining layer; and
a second bank above the first bank, and comprising a side surface that protrudes more than a side surface of the first bank and that is depressed more than the side surface of the pixel-defining layer,
wherein a distance between the side surface of the pixel-defining layer and the side surface of the second bank adjacent to the first emission area is greater than a distance between the side surface of the pixel-defining layer and the side surface of the second bank adjacent to the second emission area.

2. The display device of claim 1, wherein an area of the second emission area is greater than an area of the first emission area.

3. The display device of claim 2, wherein a distance between the side surface of the second bank and the side surface of the first bank adjacent to the first emission area is greater than a distance between the side surface of the second bank and the side surface of the first bank adjacent to the second emission area.

4. The display device of claim 1, wherein, in plan view, the pixel-defining layer comprises exposed areas that are not covered with the second bank, and
wherein a width of one of the exposed areas of the pixel-defining layer surrounding the first emission area is greater than a width of another of the exposed areas of the pixel-defining layer surrounding the second emission area.

5. The display device of claim 2, wherein the substrate further comprises a third emission area having an area that is greater than the area of the first emission area and greater than the area of the second emission area.

6. The display device of claim 5, wherein a distance between the side surface of the pixel-defining layer and the side surface of the second bank adjacent to the third emission area is less than the distance between the side surface of the pixel-defining layer and the side surface of the second bank adjacent to the first emission area.

7. The display device of claim 6, wherein the distance between the side surface of the pixel-defining layer and the side surface of the second bank adjacent to the third emission area is less than a distance between the side surface of the pixel-defining layer and the side surface of the second bank adjacent to the second emission area.

8. The display device of claim 6, wherein the distance between the side surface of the pixel-defining layer and the side surface of the second bank adjacent to the third emission area is substantially equal to a distance between the side surface of the pixel-defining layer and the side surface of the second bank adjacent to the second emission area.

9. The display device of claim 1, wherein the first light-emitting layer comprises a first area comprising a thickness of about 95% or more of a thickness of the first light-emitting layer at a point where the thickness of the first light-emitting layer is greatest, and
wherein an area of the first area of the first light-emitting layer is about 70% or more of an area of the first emission area.

10. The display device of claim 1, wherein a resolution of the display device is about 1500 pixels per inch (ppi) or more.

11. The display device of claim 1, wherein the first common electrode and the second common electrode are spaced apart.

12. The display device of claim 1, wherein the pixel-defining layer is spaced apart from an upper surface of the first pixel electrode and an upper surface of the second pixel electrode.

13. The display device of claim 12, further comprising a residual pattern between the first pixel electrode and the pixel-defining layer, and between the second pixel electrode and the pixel-defining layer.

14. The display device of claim 1, further comprising:
a first inorganic layer above the first common electrode and the second bank; and
a second inorganic layer above the second common electrode and the second bank, and spaced apart from the first inorganic layer.

15. The display device of claim 14, wherein the first inorganic layer is spaced apart from an upper surface of the second bank, and
wherein the second inorganic layer is spaced apart from the upper surface of the second bank.

16. The display device of claim 15, further comprising an organic encapsulation layer in a space between the first inorganic layer and the second bank, and in a space between the second inorganic layer and the second bank.

17. A display device comprising:
a substrate comprising a first emission area, and a second emission area spaced apart from the first emission area and comprising a greater area than the first emission area;
a pixel-defining layer comprising side surfaces defining the first emission area and the second emission area;
a first light-emitting element above the substrate in the first emission area, and comprising a first pixel electrode, a first light-emitting layer, and a first common electrode;
a second light-emitting element above the substrate in the second emission area, and comprising a second pixel electrode, a second light-emitting layer, and a second common electrode;
a first bank above the pixel-defining layer; and
a second bank above the first bank, and comprising a side surface that protrudes more than a side surface of the first bank and that is depressed more than the side surface of the pixel-defining layer,
wherein a width of an area where the pixel-defining layer and the first light-emitting layer overlap in a thickness direction of the substrate is greater than a width of an area where the pixel-defining layer and the second light-emitting layer overlap each other in the thickness direction.

18. The display device of claim 17, wherein the first light-emitting layer comprises a first area comprising a thickness of about 95% or more of a thickness of the first light-emitting layer at a point where the thickness of the first light-emitting layer is greatest, and
wherein an area of the first area of the first light-emitting layer is about 70% or more of an area of the first emission area.

19. A display device comprising:
a substrate comprising a first emission area, a second emission area, and a third emission area spaced apart from each other;
a pixel-defining layer comprising side surfaces defining the first emission area, the second emission area, and the third emission area;
a first light-emitting element above the substrate in the first emission area, and comprising a first pixel electrode, a first light-emitting layer, and a first common electrode;
a second light-emitting element above the substrate in the second emission area, and comprising a second pixel electrode, a second light-emitting layer, and a second common electrode;
a first bank above the pixel-defining layer; and
a second bank above the first bank, and comprising a side surface that protrudes more than a side surface of the first bank and that is depressed more than the side surface of the pixel-defining layer,
wherein the first emission area, the second emission area, and the third emission area comprise different respective areas, and
wherein a distance between the side surface of the pixel-defining layer and the side surface of the second bank adjacent to the first emission area, a distance between the side surface of the pixel-defining layer and the side surface of the second bank adjacent to the second emission area, and a distance between the side surface of the pixel-defining layer and the side surface of the second bank adjacent to the third emission area are different from each other.

20. The display device of claim 19, wherein a distance between the side surface of the second bank and the side surface of the first bank adjacent to the first emission area, a distance between the side surface of the second bank and the side surface of the first bank adjacent to the second emission area, and a distance between the side surface of the second bank and the side surface of the first bank adjacent to the third emission area are substantially equal.
